(19) United States
(12) Patent Application Publication
(10) Pub. No.: US 2006/0124985 A1
(43) Pub. Date: Jun. 15, 2006

(54) Methods of forming in package integrated capacitors and structures formed thereby

(76) Inventors: Xiang Yin Zeng, Shanghai (CN); Jiangqi He, Gilbert, AZ (US); Jack Zhong, Shanghai (CN)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/345,996

(22) Filed: Feb. 1, 2006

Related U.S. Application Data
(62) Division of application No. 10/966,136, filed on Oct. 15, 2004.

(51) Int. Cl. H01L 27/108

(52) U.S. Cl. 257/308

(57) ABSTRACT

Methods of forming a microelectronic structure are described. Those methods comprise depositing a bottom electrode, depositing a dielectric layer on the bottom electrode, forming at least one via in the dielectric layer, wherein a bottom surface of the via does not contact a top surface of the bottom electrode, and depositing a top electrode on the dielectric layer.

This U.S. patent application is a divisional of U.S. patent application Ser. No. 10/966,136 filed Oct. 15, 2004.

### BACKGROUND OF THE INVENTION

As semiconductor technology advances for higher processor performance, the frequency of logic and memory devices increases for higher speed. The balance between speed performance and power consumption becomes a challenging design problem. In the power delivery loop, both for core and input/output (I/O) power, parasitic inductance and resistance associated with the die package and/or printed circuit board cause a drop in voltage available to the device, leading to performance decrease.

De-coupling capacitors are added to the package to store charges and deliver to the device when required, which may reduce voltage drop in the power delivery loop. There may be limited space available for such capacitors.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1g represent methods of forming structures according to an embodiment of the present invention.

FIG. 2 represents a graph according to an embodiment of the present invention.

FIG. 3 represents a graph according to an embodiment of the present invention.

FIG. 4 represents a structure according to an embodiment of the present invention.

FIG. 5 represents a system according to another embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic device, such as an in package capacitor structure, are described. Those methods comprise depositing a bottom electrode, depositing a dielectric layer on the bottom electrode, forming at least one via in the dielectric layer, wherein a bottom surface of the via does not contact a top surface of the bottom electrode, and depositing a top electrode on the dielectric layer. In this manner, the capacitance of such a capacitance structure may be increased without increasing the package form factor, as well as achieving a reduction in the parasitic resistance and inductance of the package.

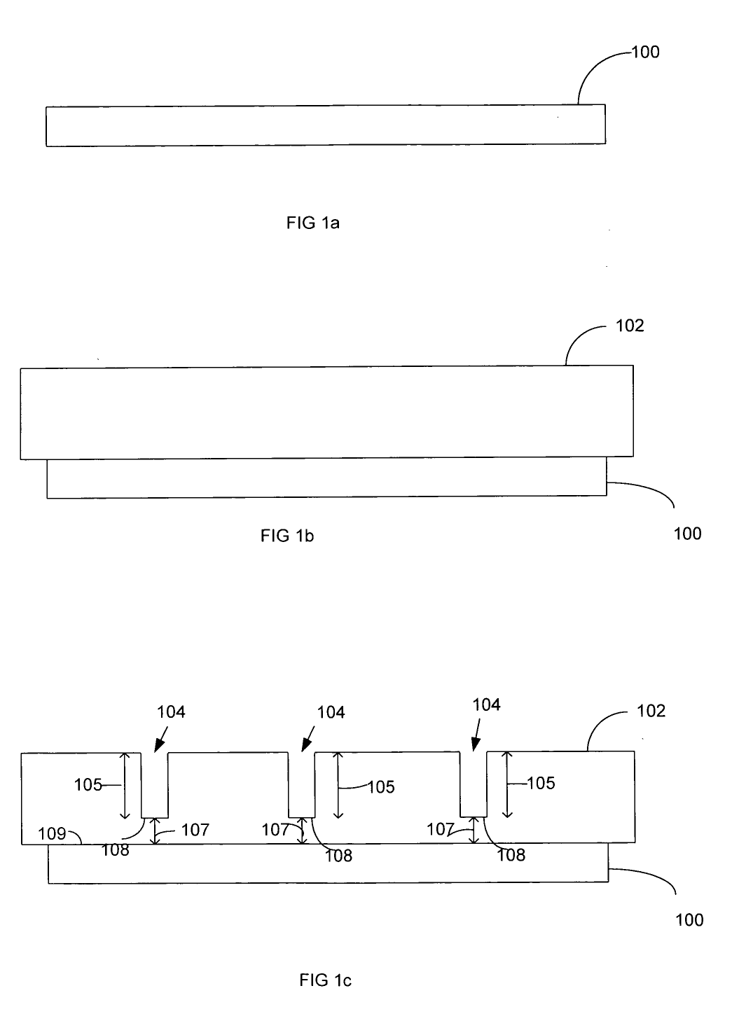

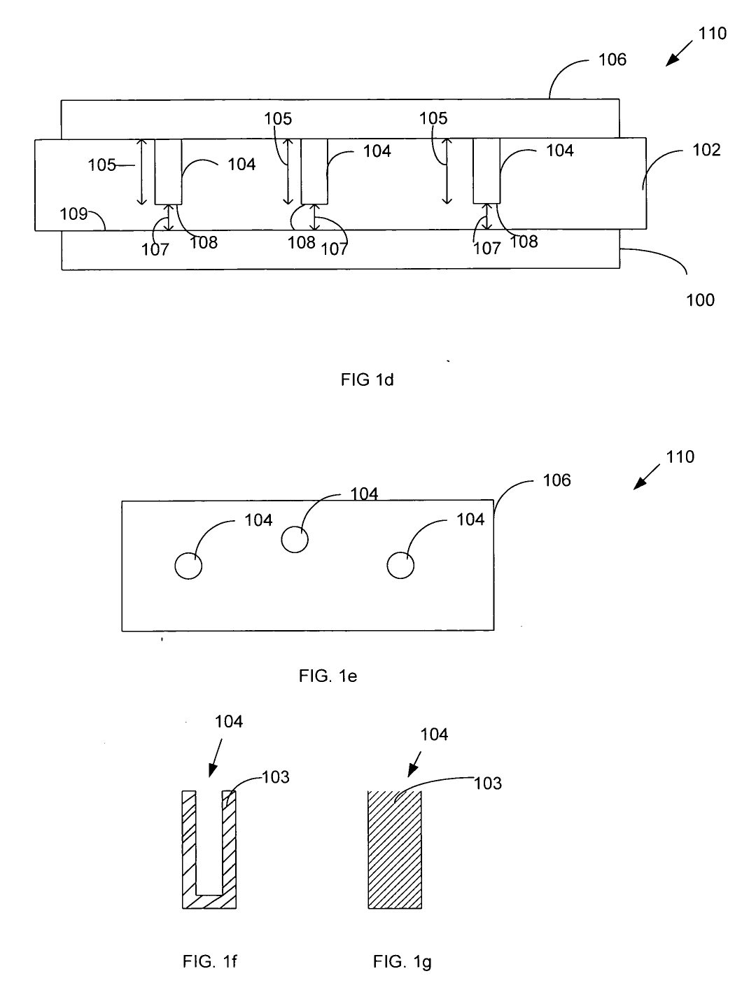

FIGS. 1a-1e illustrate an embodiment of a method of forming a microelectronic structure, such as a capacitor structure, for example. FIG. 1a illustrates a bottom electrode 100. The bottom electrode 100 may be comprised of any conductive materials as are well known in the art for fabricating electrodes of capacitor structures, such as copper, for example. A dielectric layer 102 may be formed on the bottom electrode 100 (FIG. 1b). In one embodiment, the dielectric layer 102 may comprise any such dielectric that has low loss tangent at high frequency (such as but not limited to silicon nitride and/or polyimide.

At least one via 104 may be formed in the dielectric layer 102 (FIG. 1c). The at least one via 104 may be formed utilizing any of the methods known in the art, such as laser drilling. The vias may comprise any shape, depending upon the application, such as but not limited to trapezoidal, for example. The at least one via 104 may further comprise conductive material 103, such as but not limited to copper, as is well known in the art. In one embodiment, the conductive material 103 may line the interior of the at least one via 104 (FIG. 1f). In another embodiment, the conductive material may substantially fill the at least one via 104 (FIG. 1g). Referring back to FIG. 1c, the at least one via may comprise a depth 105, which may be a function of how deep the at least one via 104 may be formed into the dielectric layer 102. The via depth 105 may be limited by the constraint that a bottom surface 108 of the at least one via 104 may not contact a top surface 109 of the bottom electrode 100.

A gap depth 107 may separate the bottom surface 108 of the at least one via 104 from the top surface 109 of the bottom electrode 100. In one embodiment, the ratio of the via depth 105 to the gap depth 107 may be greater than about 3 to 1. A top electrode 106 may be formed on the dielectric layer 104, thus forming a capacitor structure 110 (FIG. 1d). FIG. 1e depicts a top view of the vias 104 within the capacitor structure 110.

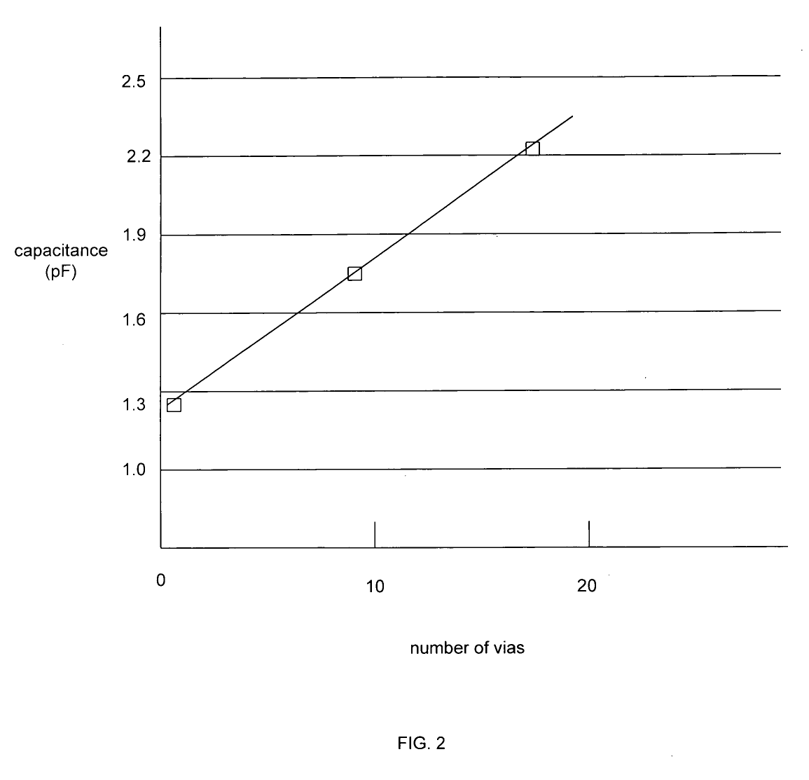

The capacitance of the capacitor structure 110 may be varied by either increasing or decreasing the number of vias 104 formed in the dielectric layer 104. In one embodiment, the capacitance of the capacitor structure 110 may be increased by increasing the number of vias 104 (FIG. 2) formed in the dielectric layer 104. The number of vias required to achieve a particular capacitance value for the capacitor structure 110 will depend on the particular application. The number of vias 104 formed for a particular application may be either substantially formed before the top electrode 106 is formed on the dielectric layer 104 and/or may be formed after the top electrode 106 is formed on the dielectric layer. Thus the capacitance of the capacitance structure 110 may be increased without increasing the capacitor area of the capacitor structure 110.

In one embodiment, the bottom electrode 100, the dielectric layer 104 and the top electrode 106 may comprise a 1 mm by 1 mm capacitor structure 110, with the dielectric layer 104 comprising a thickness of about 30 microns and a via depth of about 25 microns. The capacitance of the capacitor structure 110 in this embodiment may comprise about 2.2 pF with about 18 vias 104 formed in the dielectric layer 104, while a capacitor structure 110 with about the same dimensions, but with zero vias 104 may comprise a capacitance of about 1.29 pF.

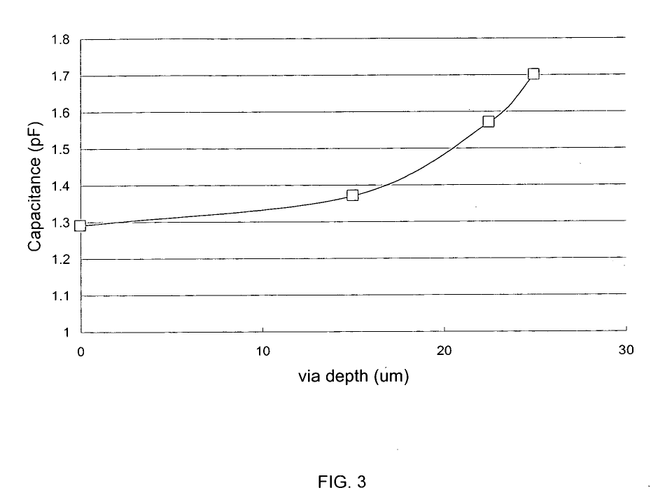

The via depth 105 may also be varied to control the capacitance of the capacitance structure 110. In one embodiment, the capacitance of the capacitor structure 110 may be increased to increase the capacitance of the capacitor structure 110 (FIG. 3). In one embodiment, with the capacitor structure 100 comprising about a 1 mm by 1 mm stack up, and the dielectric layer 102 comprising about 30 microns in depth, the capacitance for a via depth 105 of zero (no vias) may comprise about 1.29 pF, while for a similar 1 mm by 1 mm capacitor structure 110 but with a via depth 105 of 25 microns, the capacitance may comprise about 1.7 pF. It should be noted that a gap (such as gap 107 of FIG. 1d) exists between the bottom surface 108 of the via 104 and the top surface 109 of the bottom electrode 100 such that the bottom surface 108 of the via 104 does not make contact with the bottom electrode 100.

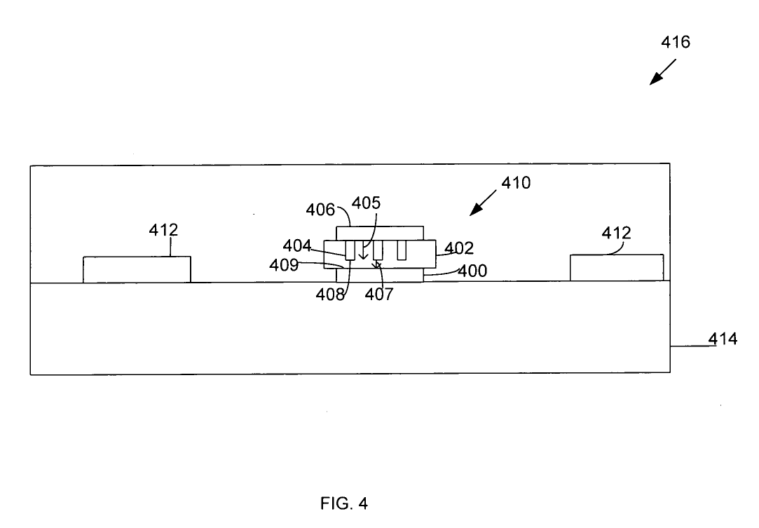

A capacitor structure 410 (similar to the capacitor structure 110 of FIG. 1d, for example) may be formed on a substrate 414 of a package 416 according to the methods of the present invention as described previously herein (FIG. 4). The substrate 414 may comprise any suitable substrate made of material such as silicon, ceramic, epoxy, and Bismaleimide Triazine (BT). The substrate 414 may also be a printed circuit board (PCB). The capacitor structure 410 may comprise a bottom electrode 400, a dielectric layer 402, at least one via 404 and a top electrode 406. The capacitor structure 410 may also comprise a top surface 409 of the bottom electrode 400, a bottom surface 408 of the via 404, and a gap depth 407 and a via depth 405.

In one embodiment, the capacitance of the capacitor structure 410 may be increased by increasing the number of vias 404 and/or increasing the via depth 405. It will be understood by those skilled in the art that the capacitance of the capacitor structure 410 may be increased while not increasing the form factor of the package 416, and/or the area of the capacitor structure 410. This provides the advantage of reducing the area utilized for capacitors for a particular package, such as a ball grid array package, or a stacked die package, as are known in the art, which may result in lower production cost and greater design freedom. Large capacitance values may be realized for RF applications, for example, without increasing the package form factor.

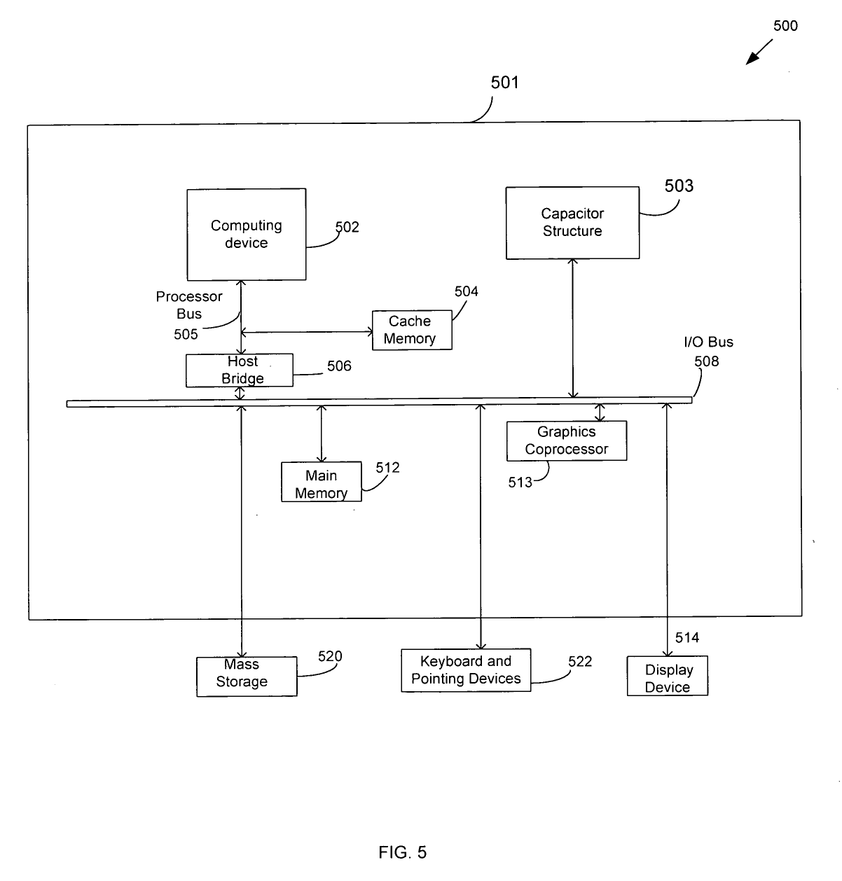

FIG. 5 is a diagram illustrating an exemplary system capable of being operated with methods for fabricating a microelectronic structure, such as the capacitor structure 110 of FIG. 1d for example. It will be understood that the present embodiment is but one of many possible systems in which the capacitor structures of the present invention may be used. The system 500 may be used, for example, to execute the processing by various processing tools, such as implanting tools, as are well known in the art, for the methods described herein.

In the system 500, a capacitor structure 503 may be communicatively coupled to a printed circuit board (PCB) 501 by way of an I/O bus 508. The communicative coupling of the capacitor structure 503 may be established by physical means, such as through the use of a package and/or a socket connection to mount the capacitor structure 503 to the PCB 501 (for example by the use of a chip package and/or a land grid array socket). The capacitor structure 503 may also be communicatively coupled to the PCB 501 through various wireless means (for example, without the use of a physical connection to the PCB), as are well known in the art.

The system 500 may include a computing device 502, such as a processor, and a cache memory 504 communicatively coupled to each other through a processor bus 505. The processor bus 505 and the I/O bus 508 may be bridged by a host bridge 506. Communicatively coupled to the I/O bus 508 and also to the capacitor structure 503 may be a main memory 512. Examples of the main memory 512 may include, but are not limited to, static random access memory (SRAM) and/or dynamic random access memory (DRAM). The system 500 may also include a graphics coprocessor 513, however incorporation of the graphics coprocessor 513 into the system 500 is not necessary to the operation of the system 500. Coupled to the I/O bus 508 may be a display device 514, a mass storage device 520, and keyboard and pointing devices 522.

These elements perform their conventional functions well known in the art. In particular, mass storage 520 may be used to provide long-term storage for the executable instructions for a method for forming capacitor structures in accordance with embodiments of the present invention, whereas main memory 512 may be used to store on a shorter term basis the executable instructions of a method for forming capacitor structures in accordance with embodiments of the present invention during execution by computing device 502. In addition, the instructions may be stored on other machine readable mediums accessible by the system, such as compact disk read only memories (CD-ROMs), digital versatile disks (DVDs), and floppy disks, for example. In one embodiment, main memory 512 may supply the computing device 502 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures, such as capacitor structures, are well known in the art. Therefore, the Figures provided herein illustrate only portions of an exemplary microelectronic device that pertains to the practice of the present invention. Thus the present invention is not limited to the structures described herein.

What is claimed is:

1. A structure comprising:
a bottom electrode;
a dielectric layer disposed on the bottom electrode;
at least one via in the dielectric layer, wherein a bottom surface of the via does not contact a top surface of the bottom electrode; and
a top electrode disposed on the dielectric layer.

2. The structure of claim 1 wherein the via comprises a laser drilled via.

3. The structure of claim 1 further comprising a gap depth between the bottom surface of the via and the top surface of the bottom electrode.

4. The structure of claim 3 wherein the ratio of the depth of the via to the gap depth is greater than about 3 to 1.

5. A structure comprising:
a capacitor on a substrate of a package, the capacitor comprising:
a bottom electrode disposed on a substrate of a package;
a dielectric layer disposed on the bottom electrode;
at least one via in the dielectric layer, wherein a bottom surface of the via does not contact a top surface of the bottom electrode; and
a top electrode disposed on the dielectric layer.

6. The structure of claim 5 further comprising a gap depth between the bottom surface of the via and the top surface of the bottom electrode, wherein the ratio of the depth of the via to the gap depth is greater than about 3 to 1.

7. The structure of claim 5 wherein the package comprises a ball grid array package.

8. A system comprising:
a capacitor structure on a substrate of a package, the capacitor structure comprising:
at least one via in a dielectric layer, wherein a bottom surface of the via does not contact a top surface of a bottom electrode;
a bus communicatively coupled to the capacitor structure; and
a DRAM communicatively coupled to the bus.

9. The system of claim 8 further comprising a gap depth between the bottom surface of the via and the top surface of the bottom electrode.

10. The system of claim 9 wherein the ratio of the depth of the via to the gap depth is greater than about 3 to 1.

11. The system of claim 8 wherein the via comprises a laser drilled via.

12. The system of claim 8 wherein the package comprises a ball grid array package.
